(19) United States
(12) Patent Application Publication
(10) Pub. No.: US 2007/0223639 A1
(43) Pub. Date: Sep. 27, 2007

(54) Phase-locked loop

(76) Inventor: Reinhold Unterricker, Vaterstetten (DE)

Correspondence Address: JENKINS, WILSON, TAYLOR & HUNT, P. A., SUITE 1200, UNIVERSITY TOWER, 3100 TOWER BOULEVARD, DURHAM, NC, 27707, US

(21) Appl. No.: 11/386,258

(22) Filed: Mar. 22, 2006

(51) Int. Cl. H03D 3/24

(52) U.S. Cl. 375/376

(57) ABSTRACT

A phase-locked loop for adjusting a phase difference between an output signal and an input signal, comprising a phase detector for generating a phase difference signal depending on a phase difference between said output signal and a phase-shifted input signal, a calculator for calculating a signal depending on said phase difference signal and an adjustable offset signal, an oscillator for generating said output signal having an oscillation frequency which is adjusted in response to said calculated signal, and a phase shifter for shifting a signal phase of said input signal by a predetermined phase in response to a control signal to generate said phase-shifted input signal applied to said phase detector.

### FIELD OF THE INVENTION

The invention relates to a phase-locked loop for adjustment of a phase difference between an output signal and an input signal.

### BACKGROUND

A phase-locked loop (PLL) is a system that uses feedback to maintain an output signal in a specific phase relationship with a reference signal. Phase-locked loops are used in many areas of electronics to control the frequency and/or phase of a signal. These applications include frequency synthesizers, modulators and demodulators as well as clock recovery circuits.

FIG. 1a shows a block diagram of a conventional phase-locked loop. A phase detector receives a reference signal which consists of a device that produces an output voltage which is proportional to a phase difference between the reference signal and a feedback signal generated by a voltage controlled oscillator VCO. The voltage controlled oscillator VCO is a circuit that produces an AC output signal whose frequency is proportional to the input control voltage. The loop filter is used to control the PLL dynamics and the performance of the phase-locked loop. The phase-locked loop is used to control the phase of the voltage controlled oscillator VCO with a reference signal in such a way that the VCO phase is equal to the phase of the reference signal.

In many applications, the phase of the voltage controlled oscillator VCO has to be trimmed, i.e. the phase of said voltage controlled oscillator VCO has to lead or to lack the reference signal by a certain phase value. In a conventional arrangement as shown in FIG. 1a, this is achieved by applying an offset signal to the output signal of the phase detector. The conventional phase-locked loop then locks in a phase-shifted state in which the phase detector PD compensates the offset signal.

Without an applied offset signal, the phase-locked loop locks at a phase difference φ=0 between the applied reference signal and the feedback signal. When applying an offset signal v_{offs}, the phase detector output signal V_{d} changes to v_{offs} and the phase difference φ=φ_{ref}−φ_{VCO} is shifted by Δφ as can be seen in FIG. 1b.

As can be seen from FIG. 1b, the conventional phase-locked loop fails to act properly for larger offsets or, equivalently, phase shifts, in particular for phase shifts larger than π. At a phase difference φ of π, there is a discontinuity which causes the voltage controlled oscillator VCO not to lock properly to the reference signal. Accordingly, the conventional phase-locked loop as shown in FIG. 1a, is limited to the working range of the phase detector PD which in the given example is a non-frequency sensitive phase detector with 2π-periodicity.

### SUMMARY

The present invention provides a phase-locked loop for adjustment of a phase difference between an output signal and an input signal which is not limited to the working range of a phase detector.

In one embodiment, the phase-locked loop for adjusting a phase difference between an output signal and an input signal according to the present invention, comprises

a phase detector for generating a phase difference signal depending on a phase difference between said output signal and the phase-shifted input signal,

a calculator for calculating a signal depending on said phase difference signal and an adjustable offset signal,

an oscillator which generates said output signal, having an oscillator frequency which is adjustable in response to said calculated signal, and

a phase shifter which shifts a signal phase of said input signal by a predetermined phase in response to a control signal to generate said phase-shifted input signal applied to said phase detector.

An advantage of the phase-locked loop according to the present invention is that the phase of the oscillator can be controlled within infinite bounds.

A further advantage of the phase-locked loop according to the present invention resides in that a non-frequency sensitive as well as a frequency sensitive phase detector can be used.

According to one embodiment of the phase-locked loop according to the present invention the input signal is formed by a periodic reference signal generated by a reference oscillator.

In accordance to a further embodiment of the phase-locked loop according to the present invention, the phase shifter is formed by an EXOR gate which logically combines said input signal with said control signal to generate said phase-shifted input signal.

In accordance with a further embodiment of the phase-locked loop according to the present invention, the EXOR gate performs a phase shift of π between said phase-shifted input signal and said input signal.

In one embodiment of the phase-locked loop according to the present invention, the phase shifter is formed by an inverting amplifier and a multiplexer which is provided for switching between a shifted and an unshifted phase operation.

In another embodiment of the phase-locked loop according to the present invention, the phase shifter comprises at least one delay element and a multiplexer.

In a still further embodiment of the phase-locked loop according to the present invention, the phase shifter comprises an analog RC filter and a multiplexer.

In one embodiment of the phase-locked loop according to the present invention, the phase-locked loop further comprises a loop filter which filters the calculated signal.

In one embodiment of the phase-locked loop according to the present invention, the loop filter comprises a low-pass filter.

In a further embodiment of the phase-locked loop according to the present invention, the oscillator comprises a voltage controlled oscillator generating a periodic oscillating signal as the output signal.

In one embodiment of the phase-locked loop according to the present invention, the phase-locked loop comprises a control circuit for generating said control signal applied to said phase shifter.

In an embodiment of the phase-locked loop according to the present invention, the control circuit further generates offset control data which is converted by a digital-to-analog converter to generate the offset signal.

In a possible embodiment of the phase-locked loop according to the present invention, the offset control data is generated by a counter provided within the control circuit.

In one embodiment of the phase-locked loop according to the present invention, the control circuit generates the control signal applied to the phase shifter when the offset control data of said counter reaches a predetermined threshold value.

In a possible embodiment of the phase-locked loop according to the present invention, when the offset signal reaches an amplitude at which said phase difference is π/2, the control circuit inverts a sign of said offset control data and applies a control signal to said phase shifter to perform a phase shift of π between said phase shifted input signal and said input signal.

In one embodiment of the phase-locked loop according to the present invention, the phase detector comprises a two-state phase detector.

In an alternative embodiment of the phase-locked loop according to the present invention, the phase detector comprises a three-state phase detector.

The invention further provides a phase-locked loop for adjustment of a phase difference between an output signal and an input signal, wherein said phase-locked loop comprises

a phase detector which generates a phase difference signal depending on a phase difference between a phase-shifted output signal and said input signal,

a calculator for calculating a signal depending on said phase difference signal and an adjustable offset signal,

an oscillator which generates said output signal having an oscillation frequency which is adjusted in response to said calculated signal, and

a phase shifter which shifts a signal phase of said output signal by a predetermined phase in response to a control signal to generate said phase-shifted output signal applied to said phase detector.

In one embodiment of the phase-locked loop, the phase shifter is formed by an EXOR gate which logically combines the output signal with said control signal to generate said phase-shifted output signal.

In an embodiment of the phase-locked loop, an EXOR gate performs a phase shift of π between said phase-shifted output signal and said output signal.

The invention further provides a phase-locked loop for adjustment of a phase difference between an output signal and an input signal wherein said phase-locked loop comprises

a phase detector which generates a phase difference signal depending on a phase difference between a phase-shifted output signal and a phase-shifted input signal,

a calculator for calculating a signal depending on said phase difference signal and an adjustable offset signal,

an oscillator which generates the output signal having an oscillation frequency which is adjustable in response to the calculated signal,

a first phase shifter which shifts a signal phase of the input signal by a first predetermined phase in response to a first control signal to generate the phase-shifted input signal applied to the phase detector, and

a second phase shifter which shifts a signal phase of the output signal by a second predetermined phase in response to a second control signal to generate the phase-shifted output signal applied to the phase detector.

In a possible embodiment of the phase-locked loop according to the present invention, the phase detector comprises a three-state phase detector.

The invention further provides a phase adjustment circuit for adjustment of a phase difference between an output signal and an input signal, wherein said phase adjustment circuit comprises

a phase-locked loop having a first input to receive a phase-shifted input signal,

a second input to receive an adjustable offset signal,

an output to output the output signal, and

a phase shifter for shifting a signal phase of the input signal by a predetermined phase in response to a control signal to generate the phase shifted input signal applied to the phase-locked loop.

The invention further provides a method for adjusting a phase difference between an output signal and an input signal,

wherein said method comprises the following steps:

shifting a signal phase of said input signal by a predetermined phase in response to the control signal to generate a phase-shifted input signal, generating a phase difference signal depending on a phase difference between the output signal and the phase-shifted input signal,

calculating a signal depending on said phase difference signal and an adjustable offset signal, and generating the output signal,

wherein the oscillation frequency of said output signal is adjusted in response to the calculated signal.

The invention further provides a method for adjusting a phase difference between an output signal and an input signal,

wherein the method comprises the following steps:

shifting a signal phase of the output signal by a predetermined phase in response to a control signal to generate a phase-shifted output signal,

generating a phase difference signal depending on a phase difference between the phase-shifted output signal and the input signal,

calculating a signal depending on said phase difference signal and an adjustable offset signal, generating the output signal,

wherein an oscillation frequency of the output signal is adjusted in response to the calculated signal.

The invention further provides a method for adjusting a phase difference between an output signal and an input signal,

wherein the method comprises the following steps:

shifting a signal phase of the input signal by a first predetermined phase in response to a first control signal to generate a phase-shifted input signal,

shifting a signal phase of the output signal by a second predetermined phase in response to a second control signal to generate a phase-shifted output signal,

generating a phase difference signal depending on a phase difference between said phase-shifted output signal and said phase-shifted input signal,

calculating a signal depending on said generated phase difference signal and an adjustable offset signal, and generating the output signal,

wherein an oscillation frequency of the output signal is adjusted in response to the calculated signal.

### BRIEF DESCRIPTION OF THE FIGURES

The invention is explained in more detail below by way of example with reference to the accompanying drawings, in which:

FIG. 1a is a block diagram of a conventional phase-locked loop;

FIG. 1b shows a diagram for illustrating the drawbacks of a conventional phase-locked loop as shown in FIG. 1a;

FIG. 2 shows a block diagram of a first embodiment of the phase-locked loop according to the present invention;

FIG. 3 shows a block diagram of an arrangement according to the present invention including a phase-locked loop according to a first embodiment;

FIGS. 4a, 4b, 4c, 4d show diagrams for illustrating the functionality of a phase-locked loop according to one embodiment of the present invention;

FIG. 5 shows a block diagram of the second embodiment of the phase-locked loop according to the present invention;

FIG. 6 shows a block diagram of the third embodiment of the phase-locked loop according to the present invention;

FIG. 7 shows a block diagram of a two-state phase detector as employed in one embodiment of the phase-locked loop according to the present invention;

FIGS. 8a, 8b show diagrams for illustrating the functionality of the two-state phase detector as shown in FIG. 7;

FIG. 9 shows a block diagram of a three-state phase detector as employed in one embodiment of the phase-locked loop according to the present invention;

FIGS. 10a, 10b, 10c show diagrams for illustrating the functionality of a phase-locked loop employing a three-state phase detector as shown in FIG. 9 according to a possible embodiment of the phase-locked loop according to the present invention;

FIG. 11 shows a block diagram of an arrangement according to the present invention;

FIG. 12 shows a flow chart according to a first embodiment of the method according to the present invention;

FIG. 13 shows a flow chart of a second embodiment of the method according to the present invention;

FIG. 14 shows a flow chart of a third embodiment of the method according to the present invention.

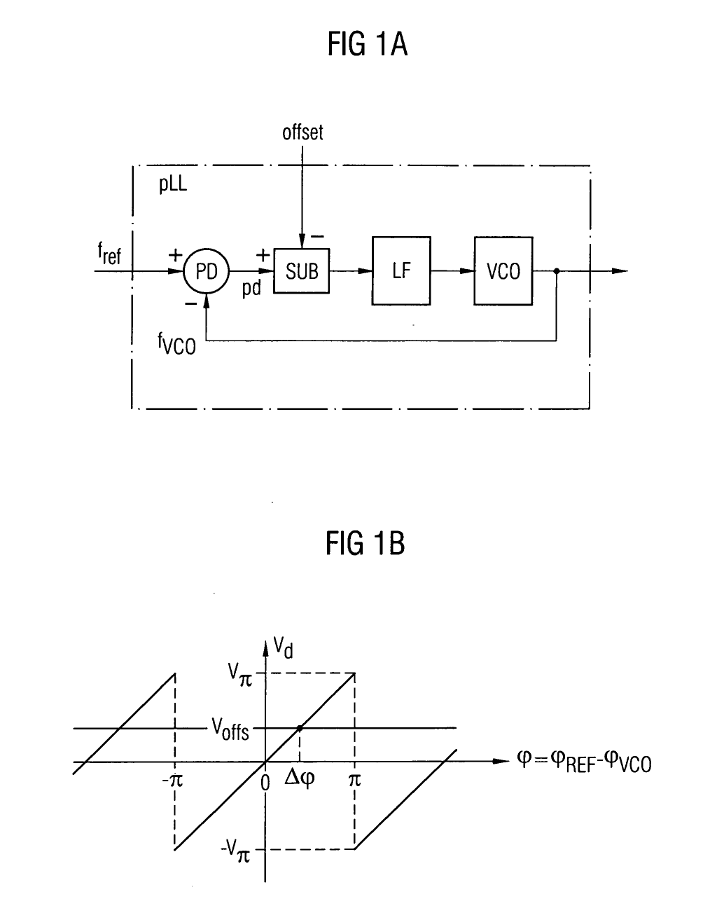

### DETAILED DESCRIPTION

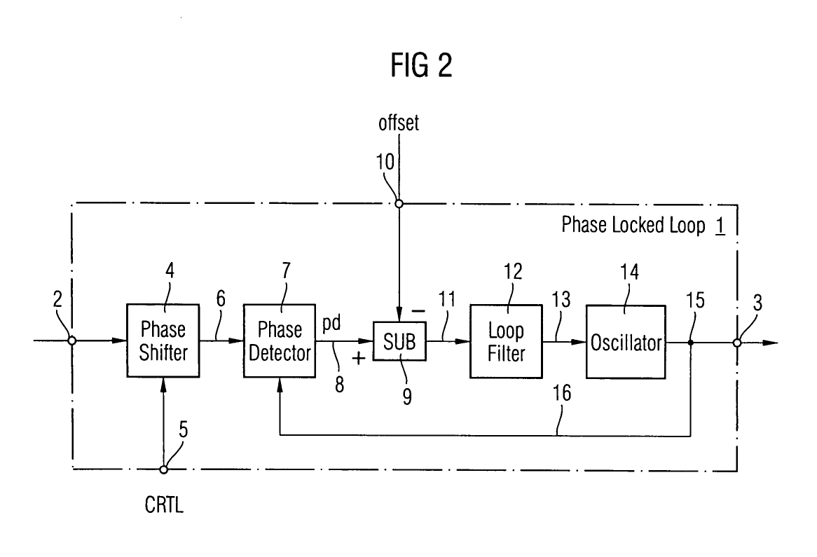

As can be seen from FIG. 2, a phase-locked loop 1 according to a first embodiment of the present invention is provided for adjustment of a phase difference between an output signal and an input signal. The phase-locked loop 1 has an input terminal 2 for applying the input signal and an output 3 terminal for outputting the output signal. The phase-locked loop 1 as shown in FIG. 2 has a phase shifter 4 which receives a control signal applied to a control input 5 of the phase-locked loop 1. The phase shifter 4 shifts a signal phase of the applied input signal by a predetermined phase in response to the control signal to generate a phase-shifted input signal which is applied via a signal line 6 to a phase detector 7 within the phase-locked loop 1. The phase detector 7 generates a phase difference signal pd depending on a phase difference between the output signal and the phase-shifted input signal. Then the phase difference signal pd is applied via a line 8 to calculator 9 for subtracting an adjustable offset signal from said phase difference signal. The offset signal is applied to an input terminal 10 of the phase-locked loop 1. The calculator 9 subtracts the applied offset signal from the phase difference signal pd to generate a calculated difference signal which is applied via a line 11 to a loop filter 12 which filters the calculated difference signal. The loop filter 12 is in one embodiment a low-pass filter. The filtered difference signal is applied via a line 13 to an oscillator 14. The oscillator 14 is in one embodiment a voltage controlled oscillator VCO. The oscillator 14 generates the output signal which has an oscillation frequency which is adjusted in response to the filtered difference signal. In a possible embodiment, the output of the calculator 9 is directly connected to the input of the oscillator 14. At a branch off node 15 the output signal is fed back via a feedback line 16 to the phase detector 7. The calculator 9 is formed in one embodiment by a substractor. In an alternative embodiment, the calculator 9 is formed by an adder.

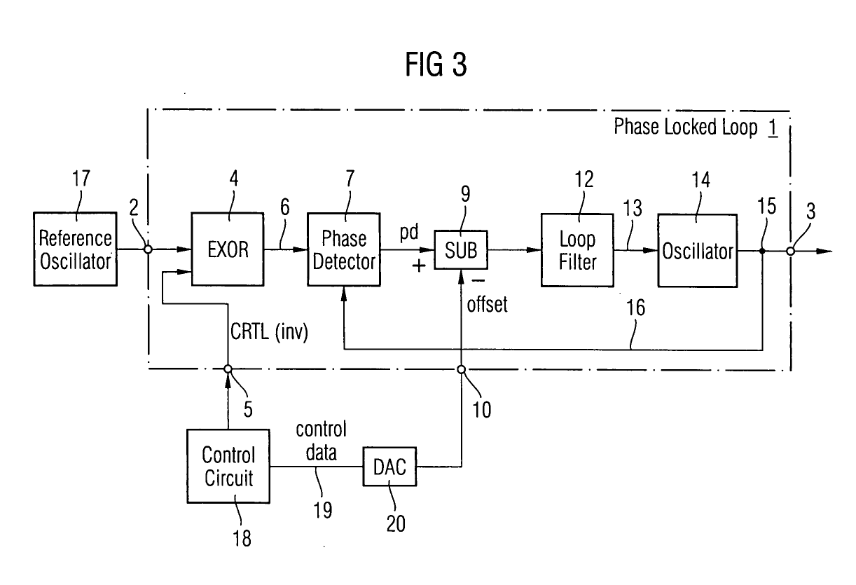

FIG. 3 shows an arrangement which comprises a phase-locked loop 1 according to the first embodiment as shown in FIG. 2. The reference signal applied to the input terminal 2 of the phase-locked loop 1 is generated by a reference oscillator 17. The reference signal is a periodic signal such as a sine wave, a sawtooth or a square wave signal.

A control circuit 18 as shown in FIG. 3 is connected to the control terminal 5 of the phase-locked loop 1 and controls the phase shifter 4 which is formed in this exemplary embodiment by an EXOR gate. Further, the control circuit 18 supplies control data via data lines 19 to a digital analog converter 20 which converts the controlled data into the offset signal applied to the calculator 9 via control terminal 10. In a possible embodiment, the control circuit 18 supplies a control signal CRTL to the phase shifter 4 when the offset control data generated by a counter of the control circuit 18 reaches a predetermined adjustable threshold count value.

In the embodiment as shown in FIG. 3, the phase shifter 4 is formed by an EXOR gate which logically combines the input reference signal with the control signal to generate a phase-shifted input signal applied to the phase detector 7. The EXOR gate 4 performs a phase shift of π between the input signal at a terminal 2 and the phase-shifted input signal applied to the input of the phase detector 7 via a line 6. The phase detector 7 generates a phase difference signal pd depending on the phase difference between the output signal at node 15 and the phase-shifted input signal output by the EXOR gate 6.

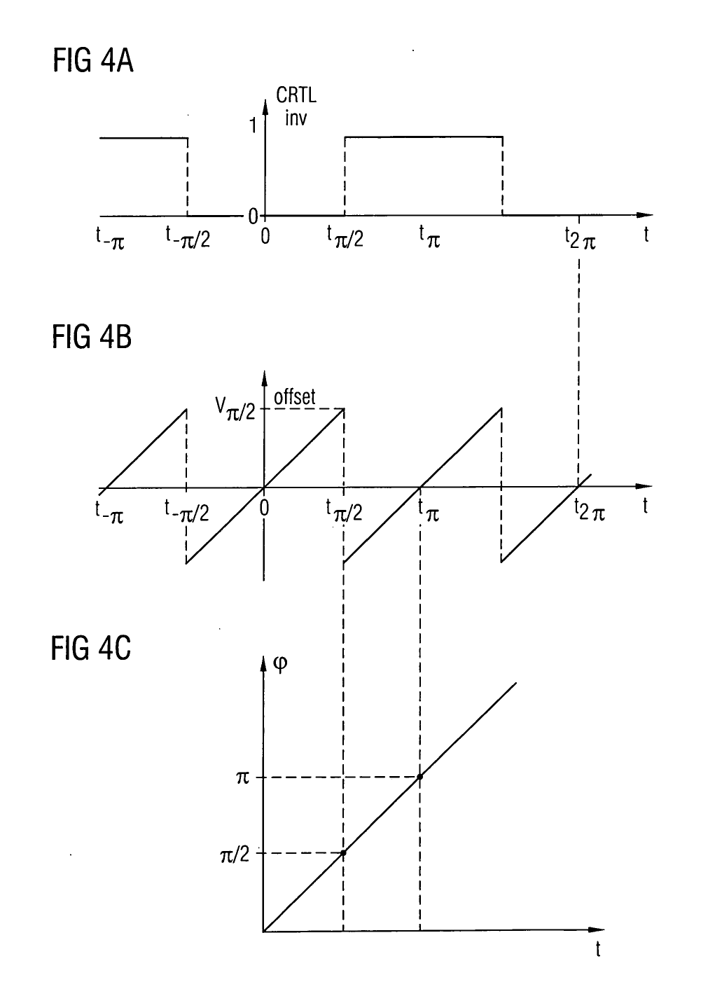

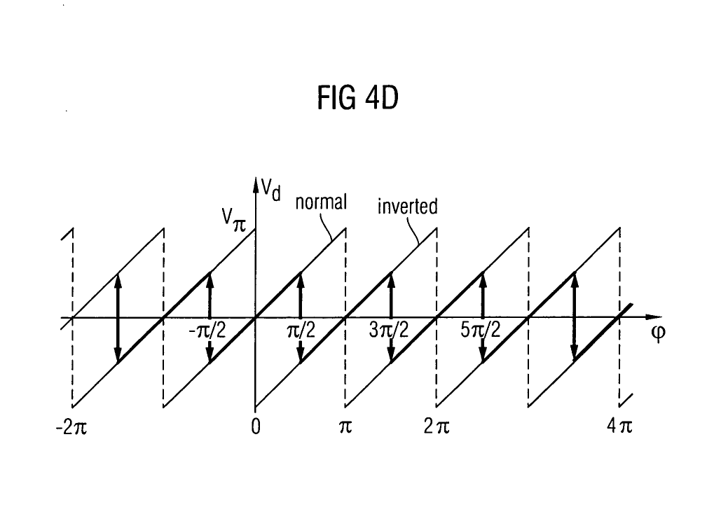

FIGS. 4a-4d illustrate the functionality of the arrangement according to the present invention as shown in FIG. 3.

When the offset signal shown in FIG. 4b generated by the control circuit 18 and converted by the digital-to-analog converter 20 reaches a predetermined threshold value a control signal CRTL generated by the control circuit 18 is applied to the phase shifter 4 being an EXOR gate. When the offset signal reaches a value at which the phase difference Δφ is π/2, the control signal CRTL generated by the control circuit 18 is switched from logically low L to logical high H at a time t_{π/2} as shown in FIG. 4a. By means of the EXOR gate 4, the applied reference signal generated by the reference oscillator 17, is inverted corresponding to a phase shift of π. When the phase difference threshold value of, for example, π/2 is reached, both, the polarity of the reference signal and the value of the offset signal are inverted as shown in FIGS. 4a, 4b. FIG. 4a shows an inversion control signal and FIG. 4b shows the offset signal to the phase detector as a function of time for a continuous phase shift in the phase-locked loop 1 according to the present invention. In the given example, V_{π}/2 is the offset voltage at which the phase shift becomes π/2. As can be seen from FIG. 4c, the phase difference φ increases continuously without a discontinuity.

FIG. 4d shows a characteristic of a phase-locked loop 1 according to the present invention employing a two-state phase detector as a phase detector 7 with a normal and an inverted reference clock. Starting from φ=0, the phase difference is trimmed on the normal characteristic until π/2. Then, the polarity of the reference signal and the sign of the offset signal are inverted by the control circuit 18 so that a phase shift between π/2 and 3 π/2 is obtained by applying offsets from −V_{π}/2 to V_{π}/2 on the inverted characteristic. At phases from 3 π/2 up to 5 π/2 the characteristic with a normal reference signal is used again an so forth. The jump between the normal characteristic and the inverted characteristic does not necessarily have to be performed at π/2. Any other value between 0 and π is possible.

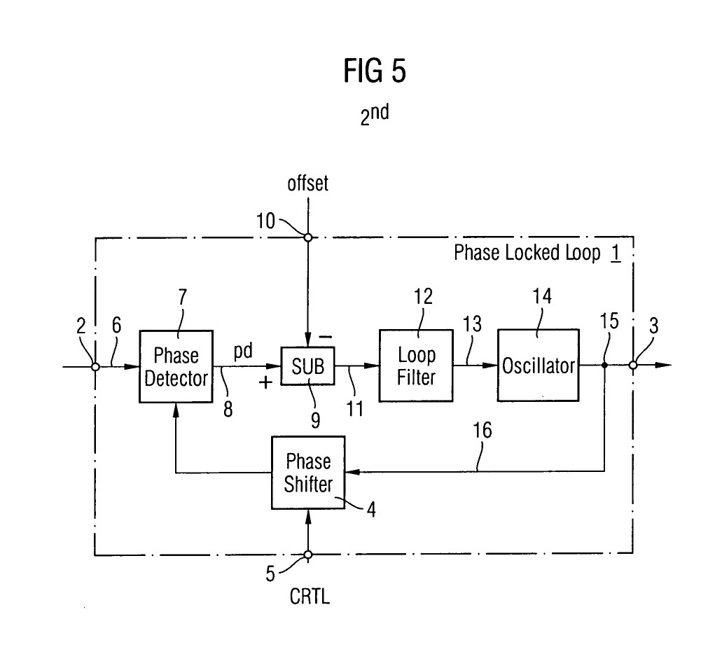

FIG. 5 shows a further embodiment of the phase-locked loop 1 according to the present invention. In this embodiment, the phase shifter 4 is provided in the feedback signal path of the phase-locked loop 1. The input signal applied to the terminal 2 is not phase-shifted but directly applied to the phase detector via a line 7. In contrast, the output signal branched off at node 15, is phase-shifted by the phase shifter 4. The phase shifter 4 shifts a signal phase of the output signal by a predetermined phase in response to a control signal CRTL applied to the control terminal 5 of the phase-locked loop 1 to generate a phase-shifted output signal applied to the phase detector 7. The phase detector 7 generates a phase difference signal pd depending on a phase difference between the phase-shifted output signal and the input signal. The calculator 9 subtracts an adjustable offset signal from the phase difference signal pd of the phase detector 7 to generate a calculated difference signal which is filtered by the loop filter 12 and applied to the oscillator 14. The oscillator 14 generates the output signal having an oscillation frequency which is adjusted in response to the filtered difference signal.

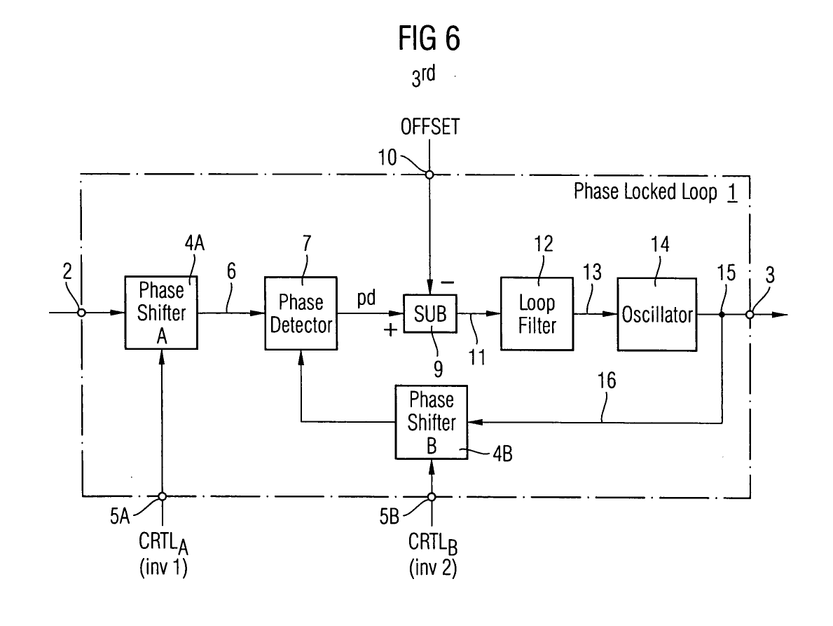

FIG. 6 shows a further embodiment of the phase-locked loop 1 according to the present invention. In this embodiment, a first phase shifter 4a is provided in a forward signal path and a second phase shifter 4b is provided in a feedback signal path. In one embodiment, the phase shifters 4a, 4b are formed by EXOR gates. The phase shifter 4a performs a phase shift of π between the phase-shifted signal applied to the phase detector 7 via a line 6 and the input reference signal applied to the terminal 2. The phase shifter 4b in the feedback signal path performs a phase shift of π between the output signal at node 15 and the phase shifted output signal applied to the phase detector 7. Both phase shifters 4a, 4b are controlled by control signals generated by a control circuit 18. The phase detector 7 generates a phase difference signal pd depending on a phase difference between the output signal phase-shifted by the second phase shifter 4b and the input signal phase-shifted by the first phase shifter 4a. The first phase shifter 4a shifts the signal phase of the applied input signal by a first predetermined phase in response to the first control signal CRTLA to generate a phase-shifted input signal applied to the phase detector 7. The second phase shifter 4b in the feedback signal path shifts a signal phase of the output signal at node 15 by a second predetermined phase in response to the second control signal CRTLB to generate the phase-shifted output signal applied to the phase detector 7. In a preferred embodiment, the phase detector 7 is formed by a three-state phase detector.

A phase shifter 4 as employed in the embodiments shown in FIGS. 2, 5, 6 are in one embodiment formed by EXOR gates. In alternative embodiments, the phase shifters 4 are formed by inverting amplifiers and multiplexers. In a still further embodiment, each phase shifter 4 is formed by at least one delay element which is serial connected and a multiplexer.

In a further embodiment, a phase shifter 4 comprises an analog RC filter and a multiplexer.

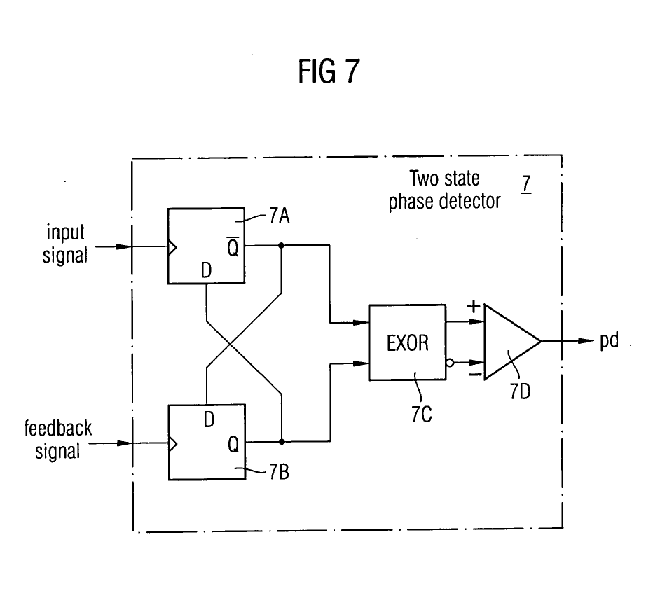

FIG. 7 shows a block diagram of a two-state phase detector 7 as used in a phase-locked loop 1 according to the present invention as in the first embodiment shown in FIG. 2 and in the second embodiment shown in FIG. 5. The two-state phase detector 7 comprises a first D-flip-flop 7a and a second D-flip-flop 7b which are triggered by the input signal and the feedback signal. The inverted output Q of the first flip-flop 7a and the output Q of the second flip-flop 7b are connected with the input terminals of an EXOR gate 7c. The EXOR gate logically combines both flip-flop states wherein the logical output signal of the EXOR gate 7c and the inverted logical output signal of the EXOR gate 7c are applied to a difference stage 7d generating a phase difference signal pd.

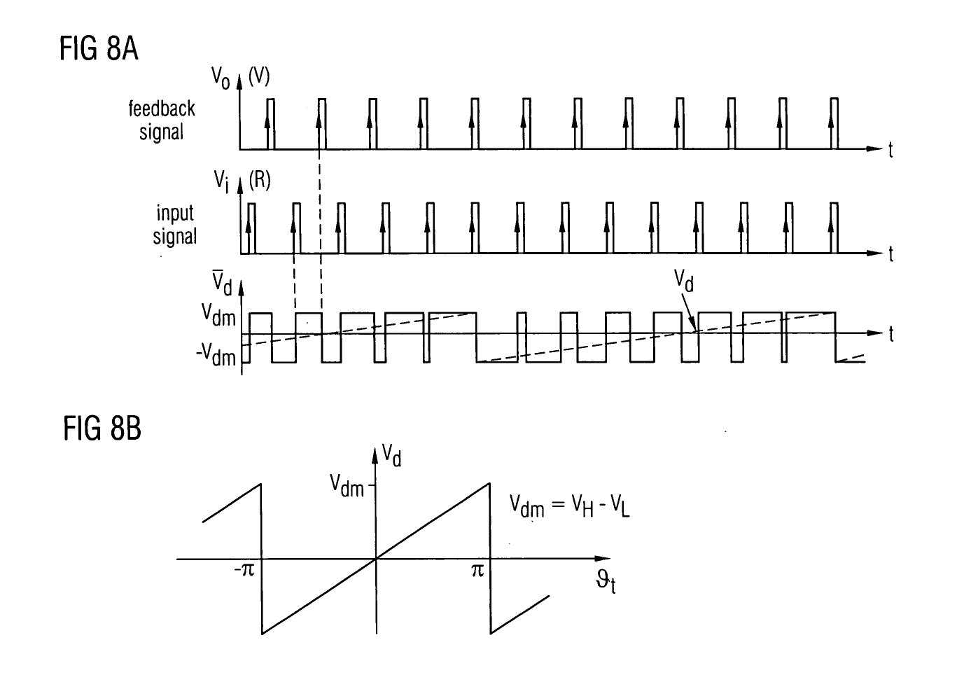

FIGS. 8a, 8b show diagrams illustrating the functionality of the two-state phase detector 7 as shown in FIG. 7. The two-state phase detector 7 as shown in FIG. 7 generates a DC-free output signal when the phase is continuously sweeping. In some phase-locked loops with its low bandwidth and a large VCO tuning range, this makes locking difficult.

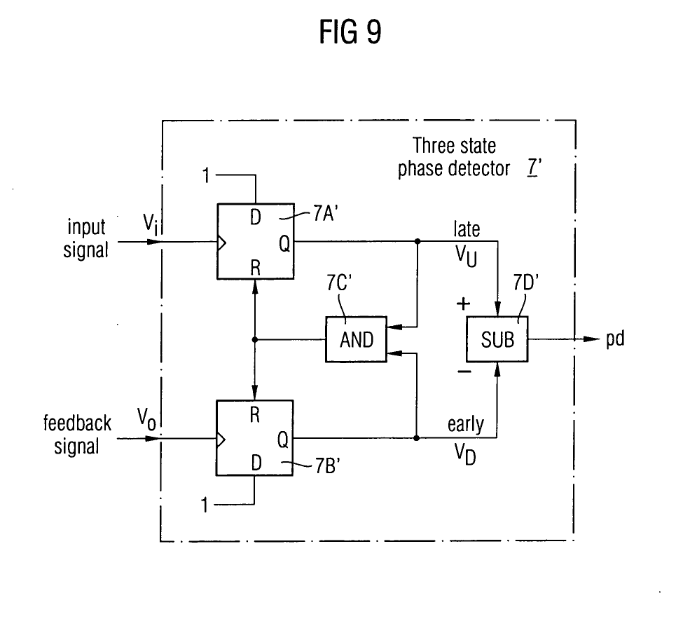

Accordingly, it is desirable to use in some applications a three-state phase detector 7′ as shown in FIG. 9. The three-state phase detector 7′ as shown in FIG. 9 includes two D-flip-flops 7a′, 7b′ which are triggered by the input signal and the feedback signal. The data inputs D of the flip-flops 7a′, 7b′ are set logically high. The reset inputs of both flip-flops 7a′, 7b′ are controlled by the output of an AND-gate logically combining the data outputs of both D-flip-flops 7a′, 7b′. Further, subtracting means 7d′ are provided for subtracting the data output Q of the second flip-flop 7b′ from data output Q of the first flip-flop 7a′ to generate a phase difference signal pd.

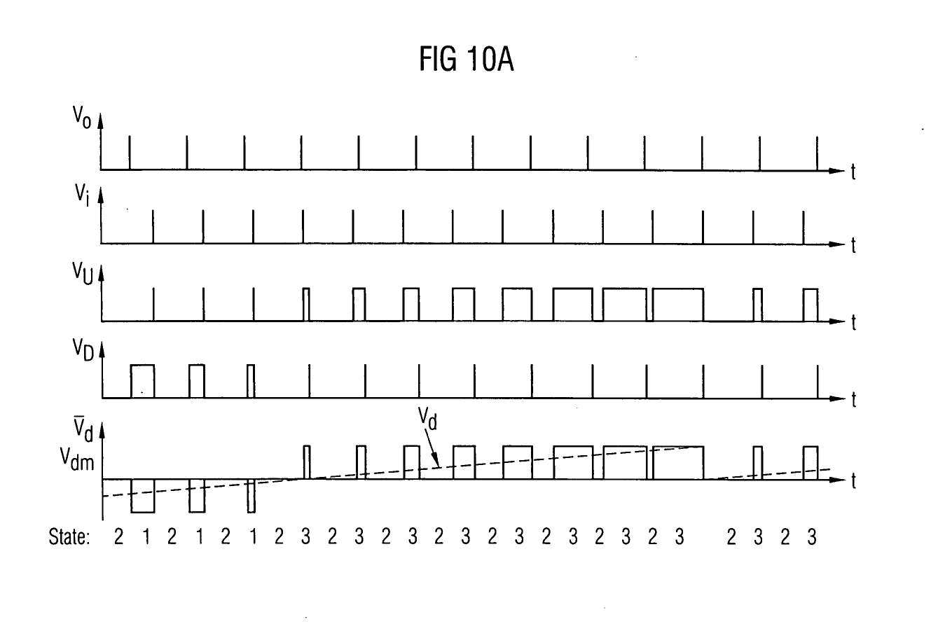

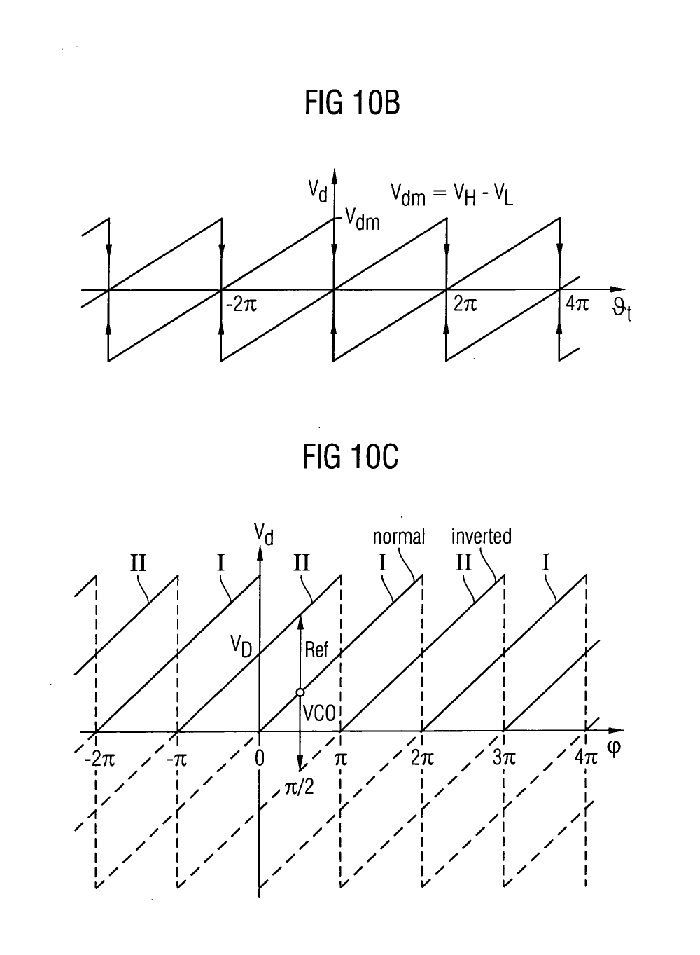

FIGS. 10a, 10b show diagrams for illustrating the functionality of the three-state phase detector as shown in FIG. 9.

FIG. 10c shows a characteristic of a three-state phase detector 7′. Lines I represent the output voltage when the phase of the voltage controlled oscillator VCO increases continuously compared with a normal reference signal. The other lines II are valid for comparison with the inverted reference signal. When the phase difference steadily decreases, the dotted lines shown in FIG. 10c are valid. As can be seen from FIG. 10c, when leaving the normal characteristic at π/2 (as with the two-state phase detector), there are different possibilities of inverted characteristics. If the phase detector jumps to the upper instead to the lower branch, a 2π-phase shift is the result because the phase is forced to shift e.g. from □/2 to −3□/2. The inversion of the reference clock generates an additional transistion in this signal, thus favouring flipflop 7A′ in FIG. 9 to be set before flipflop 7B′ which corresponds to an upper branch of the characteristic in FIG. 10b. If on the other hand the voltage controlled signal is inverted, an additional transistion signal in this signal is generated so that flipflop 7B′ in FIG. 9 is set before 7A′ which corresponds to a lower branch of the characteristic in fit. 10b. This behaviour is used to realize a continuous phase shifting of phase-locked loop with a three-state phase detector. For this end, an additional controllable inverter, i.e. EXOR gate, is inserted in the voltage control clock signal path as shown in the third embodiment of FIG. 6. The EXOR gate forms a phase shifter 4b. The phase detector 7 of FIG. 6 is formed by a three-state phase detector as shown in FIG. 9. The characteristic shown in FIG. 10c has a DC component which is dependent on the sign of the frequency deviation, i.e. the direction into which φ is changing. Accordingly, it is not necessary to provide a circuit which helps the voltage controlled oscillator VCO to lock in.

In the embodiment shown in FIG. 6 having a phase shifter 4a in the forward or reference signal path and a phase shifter 4b in the feedback signal path, it is possible to either invert the reference signal applied to an input terminal 2 or the output signal generated by the voltage control oscillator 14. When inverting the reference signal by means of the phase shifter 4a, the upper branch of the phase detector characteristic in FIG. 10c is selected while when inverting the output signal by means of the phase shift 4b, the lower branch is selected.

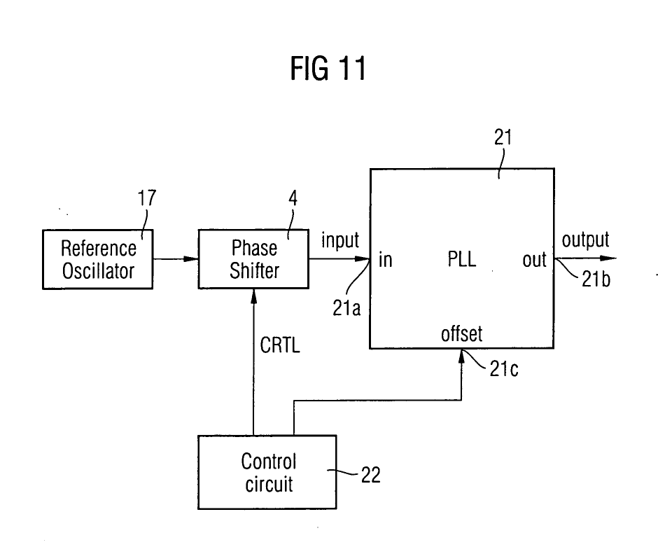

FIG. 11 shows a further arrangement according to the present invention. FIG. 11 shows a phase adjustment circuit for adjustment of a phase difference between an output signal and an input signal wherein the phase adjustment circuit comprises an integrated phase-locked loop 21 having an input terminal 21a, an output terminal 21b and a terminal 21c for applying an offset signal. The phase shifter 4 is provided for shifting a signal phase of a reference signal output by a reference oscillator 17 by a predetermined phase in response to a control signal CRTL to generate a phase-shifted input signal applied to the input terminal 21a of the phase-locked loop 21. The control signal CRTL is generated by a control circuit 22 which further generates an offset signal applied to the offset terminal 21c of the phase-locked loop 21. The phase-locked loop 21 receives the phase-shifted input signal at the terminal 21a and the adjustable offset signal at the terminal 21c. The output signal of the phase-locked loop 21 is output at the output terminal 21b. The phase shifter 4 is formed in one embodiment by an EXOR gate receiving an inversion control signal from the control circuit 22. In alternative embodiments, the phase shifter 4 is formed by an inverting amplifier, a chain of delay elements or by an analog RC filter with appropriate multiplexers or any other appropriate means to introduce a switchable delay.

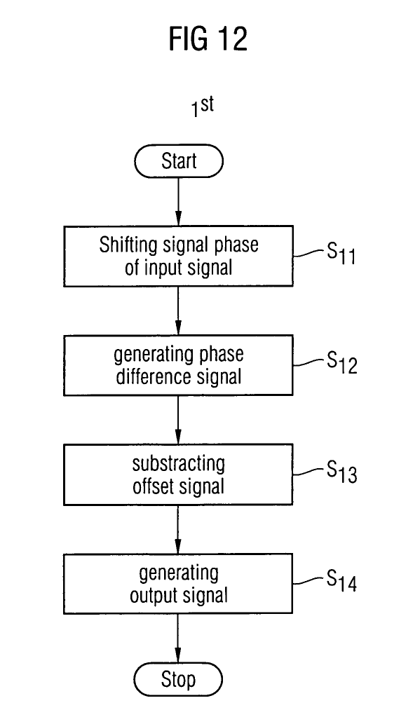

FIG. 12 shows a flow chart of a method for adjusting a phase difference between an output signal and an input signal according to a first embodiment or the present invention.

In a step S₁₁, the signal phase of an input signal is shifted by a predetermined phase in response to a control signal CRTL to generate a phase shifted input signal.

In a further step S₁₂, a phase difference signal pd is generated depending on the phase difference between an output signal and the phase-shifted input signal.

In a step S₁₃, the adjustable offset signal is subtracted from the phase difference signal pd to calculate a difference signal.

In a step S₁₄, the output signal is generated wherein an oscillation frequency of the output signal is adjusted in response to the generated difference signal.

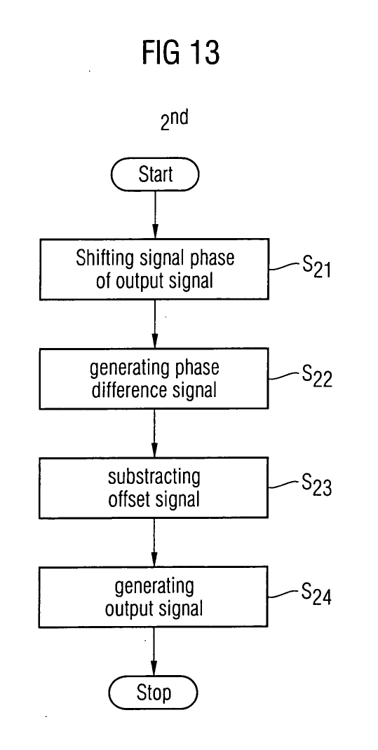

FIG. 13 shows a further embodiment of a method for adjusting a phase difference between an output signal and an input signal according to the present invention.

In a step S21, a signal phase of an oscillator output signal is shifted by a predetermined phase in response to a control signal CRTL to generate a phase-shifted output signal.

In a step S₂₂, a phase difference signal is generated depending on a phase difference between the phase-shifted output signal and an input signal.

In a step S₂₃, an adjustable offset signal is subtracted from the phase difference signal to calculate a difference signal.

Finally, in step S₂₄, the output signal is generated wherein the oscillation frequency of the output signal is adjusted in response to the calculated difference signal.

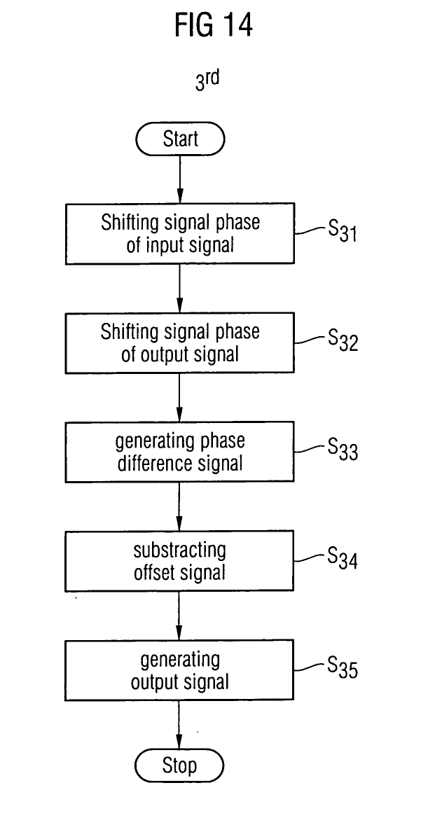

FIG. 14 shows a further embodiment of a method for adjusting a phase difference between an output signal and an input signal according to the present invention.

In a step S₃₁, the signal phase of an input signal is shifted by a predetermined phase in response to a first control signal CRTLA to generate a phase-shifted input signal.

In a step S₃₂, the signal phase of the output signal is shifted by a predetermined phase in response to a second control signal CRTLB to generate a phase-shifted output signal.

In a step S₃₃, a phase difference signal pd is generated depending on a phase difference between the phase-shifted output signal and the phase-shifted input signal.

In a step S₃₄, an adjustable offset signal is subtracted from the phase difference signal pd to calculate a difference signal.

In a step S₃₅, the output signal is generated wherein an oscillation frequency of the output signal is adjusted in response to the calculated difference signal.

In an embodiment of the phase-locked loop 1 according to the present invention, the phase shifter 4 is formed by an EXOR gate for phase inversion. This phase inversion is preferably symmetrical with respect to gate delay in order to avoid phase shift discontinuity at the switching points.

The phase-locked loop 1 according to the present invention can be used in particular in plesiochronous communication systems. The phase-locked loop 1 according to the present invention is usable in high-speed interfaces with continuous infinite phase adjustment such as DDR3, GDDR5 interfaces. The phase-locked loop 1 according to the present invention allows to control a voltage controlled oscillator VCO within infinite bounds using non-frequency sensitive as well as frequency sensitive phase detectors.

1. A phase-locked loop for adjusting a phase difference between an output signal and an input signal,
comprising:
a phase detector for generating a phase difference signal depending on a phase difference between said output signal and a phase-shifted input signal;
a calculator for calculating a signal depending on said phase difference signal and an adjustable offset signal;
an oscillator for generating said output signal having an oscillation frequency which is adjusted in response to said calculated signal; and
a phase shifter for shifting a signal phase of said input signal by a predetermined phase in response to a control signal to generate said phase-shifted input signal applied to said phase detector.

2. The phase-locked loop according to claim 1,
wherein
said input signal is a periodic reference signal generated by a reference oscillator.

3. The phase-locked loop according to claim 1,
wherein
said phase shifter is formed by an EXOR gate which logically combines said input signal with said control signal to generate said phase-shifted input signal.

4. The phase-locked loop according to claim 3,
wherein
the EXOR gate performs a phase shift of 17 between said phase-shifted input signal and said input signal.

5. The phase-locked loop according to claim 1,
wherein
said phase shifter comprises an inverting amplifier.

6. The phase-locked loop according to claim 1,
wherein
said phase shifter comprises at least one delay element.

7. The phase-locked loop according to claim 1,
wherein
said phase shifter comprises an analogue RC-filter.

8. The phase-locked loop according to claim 1,
wherein
said phase-locked loop further comprises a loop filter for filtering said calculated signal.

9. The phase-locked loop according to claim 8,
wherein
said loop filter comprises a low-pass filter.

10. The phase-locked loop according to claim 1,
wherein
said oscillator comprises a voltage controlled oscillator generating a periodic oscillating signal as said output signal.

11. The phase-locked loop according to claim 1,
wherein
said phase-locked loop further comprises a control circuit for generating said control signal applied to said phase shifter.

12. The phase-locked loop according to claim 11,
wherein
said control circuit further generates offset control data which is converted by a digital/analogue converter to said offset signal.

13. The phase-locked loop according to claim 12,
wherein
said offset control data is generated by a counter provided within said control circuit.

14. The phase-locked loop according to claim 13,
wherein
the control circuit generates said control signal applied to said phase shifter when the offset control data of said counter reaches a predetermined threshold value.

15. The phase-locked loop according to claim 1,
wherein
when the offset signal reaches an amplitude at which said phase difference is π/2,
the control circuit inverts a sign of said offset control data and applies a control signal to said phase shifter to perform a phase shift of π between said phase-shifted input signal and said input signal.

16. The phase-locked loop according to claim 1,
wherein
said phase detector comprises a two-state phase detector.

17. A phase-locked loop for adjusting a phase difference between an output signal and an input signal,
said phase-locked loop comprising:
a phase detector for generating a phase difference signal depending on a phase difference between a phase-shifted output signal and said input signal;
(a) a calculator for calculating a signal depending on said phase difference signal and an adjustable offset signal;
an oscillator for generating said output signal having an oscillation frequency which is adjusted in response to said calculated signal; and
a phase-shifter for shifting a signal phase of said output signal by a predetermined phase in response to a control signal to generate said phase shifted output signal applied to said phase detector.

18. The phase-locked loop according to claim 17,
wherein
said phase shifter is formed by an EXOR gate which logically combines said output signal with said control signal to generate said phase-shifted output signal.

19. The phase-locked loop according to claim 18,
wherein
the EXOR gate performs a phase shift of π between said phase-shifted output signal and said output signal.

20. A phase-locked loop for adjustment of a phase difference between an output signal and an input signal,
said phase-locked loop comprising:
a phase detector for generating a phase difference signal depending on
a phase difference between a phase-shifted output signal and a phase-shifted input signal;
a calculator for calculating a signal depending on said phase difference signal and an adjustable offset signal;
an oscillator which generates said output signal having an oscillation frequency which is adjustable in response to said calculated signal;
a first phase shifter which shifts a signal phase of said input signal by a first predetermined phase in response to a first control signal to generate said phase-shifted input signal applied to said phase detector; and
a second phase shifter which shifts a signal phase of said output signal by a second predetermined phase in response to a second control signal to generate said phase-shifted output signal applied to said phase detector.

21. The phase-locked loop according to claim 20,
wherein
said phase detector comprises a three-state phase detector.

22. A phase adjustment circuit for adjusting a phase difference between an output signal and an input signal,
said phase adjustment circuit comprising:
a phase locked loop having a first input to receive a phase-shifted input signal,
a second input to receive an adjustable offset signal, and
an output to output said output signal; and
a phase shifter for shifting a signal phase of said input signal by a predetermined phase in response to a control signal to generate said phase-shifted input signal applied to said phase-locked loop.

23. A method for adjusting a phase difference between an output signal and an input signal,
said method comprising the following steps:
shifting a signal phase of said input signal by a predetermined phase in response to a control signal to generate a phase-shifted input signal;
generating a phase difference signal depending on a phase difference between said output signal and said phase shifted input signal;
calculating a signal depending on said phase difference signal and an adjustable offset signal;
generating said output signal,
wherein
said oscillation frequency of said output signal is adjusted in response to said calculated signal.

24. A method for adjusting a phase difference between an output signal and an input signal,
said method comprising the following steps:
shifting a signal phase of said output signal by a predetermined phase in response to a control signal to generate a phase shifted output signal;
generating a phase difference signal depending on a phase difference between said phase shifted output signal and said input signal;
calculating a signal depending on said phase difference signal and an adjustable offset signal;
generating said output signal,
wherein
an oscillation frequency of said output signal is adjusted in response to said calculated signal.

25. A method for adjusting a phase difference between an output signal and an input signal,
said method comprising the following steps:
shifting a signal phase of said input signal by a predetermined phase in response to a first control signal to generate a phase-shifted input signal;
shifting a signal phase of said output signal by a predetermined phase in response to a second control signal to generate a phase-shifted output signal;
generating a phase difference signal depending on a phase difference between said phase-shifted output signal and said phase-shifted input signal;
calculating a signal depending on said phase difference signal and an adjustable offset signal;
generating said output signal,
wherein
an oscillation frequency of said output signal is adjusted in response to said calculated signal.

26. The method according to claims 23, 24, 25,
wherein
the offset signal is substracted from said phase difference signal.

27. The method according to claims 23, 24, 25,
wherein
the offset signal is added to said phase difference signal.
